(19) United States
(12) Patent Application Publication
(10) Pub. No.: US 2025/0259942 A1
(43) Pub. Date: Aug. 14, 2025

(54) SEMICONDUCTOR PACKAGE

(71) Applicant: Samsung Electronics Co., Ltd., Suwon-si (KR)

(72) Inventor: Jongmin KIM, Suwon-si (KR)

(73) Assignee: Samsung Electronics Co., Ltd., Suwon-si (KR)

(21) Appl. No.: 18/930,030

(22) Filed: Oct. 29, 2024

(30) Foreign Application Priority Data
Feb. 8, 2024 (KR) 10-2024-0019490

(51) Int. Cl. H01L 23/552; H01L 23/31; H01L 23/538; H01L 25/16

(52) U.S. Cl. CPC H01L 23/552; H01L 23/5385; H01L 25/16; H10D 1/20; H10D 1/692; H01L 23/3107

(57) ABSTRACT

A semiconductor package includes a package substrate, a semiconductor chip disposed on the package substrate, an encapsulant covering the semiconductor chip and at least a portion of the package substrate, a shield layer covering at least a portion of each of the encapsulant and the package substrate, and an inductor connected to the shield layer to form an LC resonant circuit. The shield layer may include a first conductive layer covering at least a portion of each of the encapsulant and the package substrate and configured to be applied with a first voltage, a dielectric layer on the first conductive layer, and a second conductive layer on the dielectric layer and designed to be applied with a second voltage.

### CROSS-REFERENCE TO RELATED APPLICATION(S)

This U.S. non-provisional application claims priority under 35 USC § 119 to Korean Patent Application No. 10-2024-0019490, filed on Feb. 8, 2024, in the Korean Intellectual Property Office, the disclosure of which is herein incorporated by reference in its entirety.

### BACKGROUND

Example embodiments relate to a semiconductor package.

With the miniaturization and high-performance of electronic devices, there is increasing demand for packages allowing for protection of semiconductor chips from electromagnetic interference (EMI). Research and development are continuously being conducted on semiconductor packages with EMI shielding structures introduced, for example, outside or at a periphery of the semiconductor package.

### SUMMARY

Example embodiments relate to a semiconductor package with significantly reduced electromagnetic interference (EMI) and/or noise.

According to some example embodiments, a semiconductor package may include a package substrate, a semiconductor chip on the package substrate, an encapsulant covering the semiconductor chip and at least a portion of the package substrate, a shield layer covering at least a portion of the encapsulant and of the package substrate, and an inductor connected to the shield layer as to form an LC resonant circuit. The shield layer may include a first conductive layer covering at least a portion of the encapsulant and of the package substrate and configured to have a first voltage applied thereto, a dielectric layer on the first conductive layer, and a second conductive layer on the dielectric layer and configured to have a second voltage be applied thereto.

The shield layer may form a capacitor, and the inductor may be connected in parallel to the capacitor.

The inductor may have a first terminal and a second terminal, the first terminal electrically connected to the first conductive layer, and the second terminal electrically connected to the second conductive layer.

The shield layer may form a capacitor, and the inductor may be connected in series to the capacitor.

The first conductive layer may be configured to have a first voltage applied thereto, and the second conductive layer may be configured to have a second voltage applied thereto, the second voltage different from the first voltage. The first voltage may be a power supply voltage, and the second voltage may be a ground voltage.

The shield layer may further include a third conductive layer between the dielectric layer and the second conductive layer.

The semiconductor package may further include a conductive structure in contact with an outer side surface of the second conductive layer and electrically connected to the second conductive layer, and a base substrate below the package substrate and the conductive structure.

The inductor may have a first terminal electrically connected to the first conductive layer, and the inductor may have a second terminal electrically connected to the second conductive layer through the conductive structure.

The first conductive layer, the dielectric layer, and the second conductive layer may cover at least a portion of an upper surface and a side surface of the encapsulant and a side surface of the package substrate.

The first conductive layer may cover a portion of the encapsulant, the dielectric layer may be in contact with the side surface of the encapsulant and at least a portion of the upper surface of the package substrate, and the second conductive layer may cover the encapsulant, the upper surface of the package substrate, and the side surface of the package substrate.

The semiconductor package may further include a connection line at least partially extending through the encapsulant and electrically connecting the first conductive layer with a first terminal of the inductor.

The inductor may be embedded in the package substrate.

The semiconductor chip may include a plurality of semiconductor chips, and the inductor may be provided between ones of the plurality of semiconductor chips. The semiconductor chip may be configured as a flip chip.

The inductor may be apart from the encapsulant and from the shield layer.

The package substrate may include upper pads, lower pads, and a first interconnection structure electrically connecting a first upper pad of the upper pads and a first lower pad of the lower pads.

A portion of the first interconnection structure may be electrically connected to at least one of the first conductive layer or the second conductive layer.

### BRIEF DESCRIPTION OF DRAWINGS

The above and other aspects, features, and advantages of example embodiments of inventive concepts will be more clearly understood from the following detailed description, taken in conjunction with the accompanying drawings.

FIG. 1 is a plan view of a semiconductor package according to some example embodiments.

FIG. 2 is a cross-sectional view taken along line A-A′ of the semiconductor package of FIG. 1.

FIG. 3 is a cross-sectional view of a semiconductor package according to some example embodiments.

FIG. 4 is a cross-sectional view of a semiconductor package according to some example embodiments.

FIG. 5 is a cross-sectional view of a semiconductor package according to some example embodiments, illustrating that a semiconductor chip is provided in plural.

FIG. 6 is a cross-sectional view illustrating that a semiconductor chip is provided as a flip chip in some example embodiments.

FIG. 7 is a schematic cross-sectional view of a semiconductor package according to some example embodiments, illustrating that an inductor is embedded within the package substrate.

FIG. 8 is a cross-sectional view of a semiconductor package according to some example embodiments, illustrating that a conductive structure is formed to be different from a conductive structure according to the above-described embodiment.

FIG. 9 is a cross-sectional view of a semiconductor package according to some example embodiments, illustrating that a location of the inductor is different from locations in the above-described embodiments.

FIG. 10 is a cross-sectional view of a semiconductor package according to some example embodiments.

FIG. 11 is a cross-sectional view of a semiconductor package according to some example embodiments.

FIGS. 12A and 12B are cross-sectional views of a package substrate according to some example embodiments, respectively.

### DETAILED DESCRIPTION

Inventive concepts may be modified in various ways, and may have various example embodiments, among which some specific example embodiments will be described in detail with reference to the accompanying drawings. However, it should be understood that the description of specific example embodiments of inventive concepts is not intended to limit inventive concepts to a particular mode of practice, and that inventive concepts are to cover all modifications, equivalents, and substitutes included in the spirit and technical scope as understood by one of ordinary skill in the art.

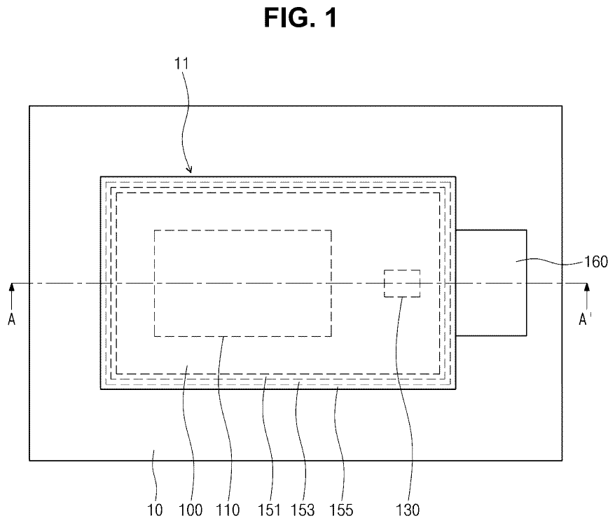

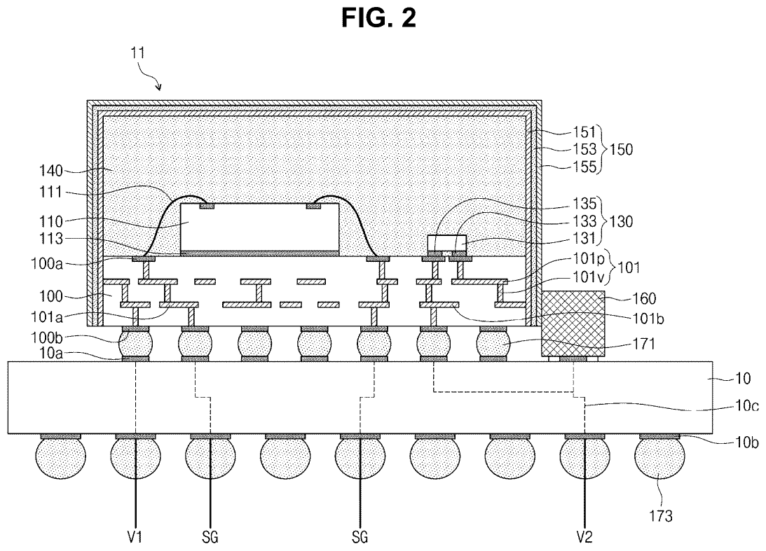

FIG. 1 is a plan view of a semiconductor package according to some example embodiments, and FIG. 2 is a cross-sectional view taken along line A-A′ of the semiconductor package of FIG. 1.

Referring to FIGS. 1 and 2, a semiconductor package of some example embodiments may include a package body 11, including a semiconductor chip 110, and a base substrate 10 on which the package body 11 is located (for example, mounted). A conductive structure 160, electrically connected to the package body 11, may be provided on the base substrate 10. The package body 11 may include the semiconductor chip 110, a package substrate 100 on which the semiconductor chip 110 is mounted, an encapsulant 140 encapsulating or at least partially encapsulating the semiconductor chip 110, a shield layer 150 provided on the encapsulant 140, and an inductor 130 electrically connected to the shield layer 150.

The semiconductor chip 110 may include one or more semiconductor chips provided on an upper surface of the package substrate 100. The semiconductor chip 110 may be or include a semiconductor device including an integrated circuit. A semiconductor chip may be provided in the form of or as part of a package. In some example embodiments, a semiconductor package may have a package-on-package (POP) structure. An integrated circuit (IC) may be generally formed by forming an electronic circuit on a semiconductor material such as silicon, and may be implemented by integrating a plurality of transistors, capacitors, inductors, resistors, or the like, into a die (or a semiconductor chip).

In some example embodiments, the semiconductor chip 110 may be or include, for example, a logic semiconductor chip, a memory semiconductor chip, or a combination thereof. For example, the logic semiconductor chip may be or include an application processor (AP), a microprocessor, a central processing unit (CPU), a controller, a graphics processor unit (GPU), a system-on-a-chip (SoC), and/or an application specific integrated circuit (ASIC). In addition, the memory semiconductor chip may be a volatile memory such as a dynamic random access memory (DRAM), a static random access memory (SRAM), or a nonvolatile memory such as a phase-change random access memory (PRAM), a magneto-resistive random access memory (MRAM), a ferroelectric random access memory (FeRAM), or a resistive random access memory (RRAM), but example embodiments are not limited thereto. In some example embodiments, the semiconductor chip 110 may include memory chips or memory elements, which may store and/or output data based on address commands and control commands received from the package substrate 100, among the above-described various semiconductor chips. The semiconductor chip 110 may be attached to the upper surface of the package substrate 100 using an adhesive element 113 (for example, a die attach film). The semiconductor chip 110 may be electrically connected to the package substrate 100 through conductive wires 111 connected to conductive pads of the semiconductor chip 110 and first upper pads 100a of the package substrate 100, but example embodiments are not limited thereto.

The package substrate 100 may transmit signals from the semiconductor chip 110, disposed thereon, to the outside. In addition, or alternatively, the package substrate 1000 may transmit signals and power from the outside to the semiconductor chip 110. The package substrate 100 may include, for example, interconnections for transmitting signals and power, or the like. The interconnections of the package substrate 100 may include first upper pads 100a, first lower pads 100b, and a first interconnection structure 101.

The package substrate 100 may include or be formed of, for example, an insulating material. For example, the package substrate 100 may include an insulating resin. The insulating resin may include, for example, a thermosetting resin such as an epoxy resin, a thermoplastic resin such as polyimide, or a resin impregnated with an inorganic filler in these resins, for example, prepreg, Ajinomoto Build-up Film (ABF), flame retardant (FR-4), and/or Bismaleimide Triazine (BT), but example embodiments are not limited thereto. For example, the package substrate 100 may include a photosensitive resin such as, for example, a photoimageable dielectric (PID). The package substrate 100 may include a plurality of insulating layers, not illustrated, which may be, for example, stacked in a vertical direction. Depending on process(es), boundaries between the plurality of insulating some example embodiments, the material(s) of the package substrate 100 is not limited to the above materials, and the package substrate 100 may be a semiconductor substrate formed of other silicon material(s). For example, in other example embodiments, the package substrate 100 may include, for example, semiconductor elements such as, for example, germanium (Ge) or a compound semiconductor such as, for example, silicon carbide (SiC), gallium arsenide (GaAs), indium arsenide (InAs), and/or indium phosphide (InP), but example embodiments are not limited thereto.

In addition, or alternatively, to semiconductor chip 110 and inductors 13, various active and/or passive microelectronic devices may be provided on the package substrate 100. For example, the package substrate 100 may include, for example, a complementary metal-insulator-semiconductor (CMOS) transistor, a metal-oxide-semiconductor field effect transistor (MOSFET), a system large scale integration (LSI), a CMOS imaging sensor (CIS), a micro-electro-mechanical system (MEMS), and/or the like, but example embodiments are not limited thereto.

The first upper pads 100a may be disposed above the package substrate 100. An upper surface of the first upper pad 100a may be exposed upwardly of the upper surface of the package substrate 100. The first upper pad 100a may include at least one of, for example, aluminum (Al), gold (Au), cobalt (Co), copper (Cu), nickel (Ni), lead (Pb), tantalum (Ta), tellurium (Te), titanium (Ti), tungsten (W), silver (Ag), molybdenum (Mo), zinc (Zn), platinum (Pt), or any combinations thereof, but example embodiments are not limited thereto. A first lower pad 100b may be disposed below the package substrate 100 and may include a material, similar to the material of the first upper pad 100a. However, the materials of the first upper pad 100a and the first lower pad 100b are not limited to the above materials. In some example embodiments, each of the first upper pad 100a and the first lower pad 100b is illustrated as being formed in a single pattern, but example embodiments are not limited thereto and two or more stacked patterns may be provided.

The first interconnection structure 101 may be formed of a conductive material having at least one layer, for example, a plurality of layers, within the package substrate 100. For example, the first interconnection structure 101 may be formed of at least one of aluminum (Al), gold (Au), cobalt (Co), copper (Cu), nickel (Ni), lead (Pb), tantalum (Ta), tellurium (Te), titanium (Ti), tungsten (W), silver (Ag), molybdenum (Mo), zinc (Zn), platinum (Pt), or combinations thereof, but example embodiments are not limited thereto. The first interconnection structure 101 may be formed in a multilayer structure including interconnection patterns 101p and vias 101v. For example, the interconnection patterns 101p may be provided to transmit electrical signals and power in a lateral direction, and the vias 101v may be provided to transmit electrical signals and power in a vertical direction.

The interconnection patterns 101p and vias 101v, constituting (for example, included in) the first interconnection structure 101, may connect the first upper pads 100a and the first lower pads 100b. In some example embodiments, the first interconnection structure 101 may include signal interconnections 101a, transmitting signals and power (hereinafter referred to as “signals”) to devices within a semiconductor package such as a semiconductor chip 110, and capacitor interconnections 101b for forming an LC resonant circuit. The signal interconnections 101a and the capacitor interconnections 101b may be electrically insulated from each other. The interconnection patterns 101p and vias 101v, constituting the signal interconnections 101a, may be electrically connected to the semiconductor chip 110 through (for example, by) the first upper pads 100a. The interconnection patterns 101p and vias 101v, constituting (for example, included in) the capacitor interconnections 101b, may be directly or indirectly connected to the inductor 130 and the shield layer 150. For example, a portion of the capacitor interconnections 101b may be connected to the inductor 130 through (for example, by) the first upper pads 100a, but example embodiments are not limited thereto. Additionally, or alternatively, a portion of the capacitor interconnections 101b may contact the first conductive layer 151 of the shield layer 150 to be electrically connected thereto.

The encapsulant 140 may be provided on the package substrate 100 and may encapsulate or at least partially encapsulate the semiconductor chip 110. In plan view, the encapsulant 140 may be provided with the same, substantially the same, or similar shape and/or size as the package substrate 100, and a horizontal area of the encapsulant 140 may be the same as a horizontal area of the package substrate 100. For example, a side surface of the encapsulant 140 may be coplanar or substantially coplanar with a side surface of the package substrate 100. However, in some example embodiments, the horizontal area of the encapsulant 140 may be smaller than the horizontal area of the package substrate 100. For example, the side surface of the package substrate 100 may be disposed outside the side surface of the encapsulant 140. The encapsulant 140 may be formed of an insulating material, for example, an epoxy molding compound (EMC), but the material of the encapsulant 140 is not limited thereto.

The shield layer 150 may be provided on side surfaces and an upper surface of the package body 11 to protect the internal semiconductor chip 110 from external electromagnetic waves. For example, a shield layer may be provided in plural to improve electromagnetic interference (EMI) shielding ability of the semiconductor package. For example, the shield layer may be provided for electromagnetic shielding. Electromagnetic waves may induce EMI in a space within a semiconductor chip or a semiconductor package or another component, resulting in generation of unwanted signals or noise and degraded performance of the semiconductor package. The shield layer 150 may be provided to reduce or prevent such electromagnetic waves from penetrating through and/or interfering with a space within the semiconductor chip or semiconductor package.

The plurality of layers used in the shield layer 150 may include, for example, one or more of metal and dielectric layers, but example embodiments are not limited thereto. For example, the plurality of layers used in the shield layer 150 may have a metal-insulator-metal (MIM) structure including a conductive metal, a dielectric layer, and a conductive metal. When, for example, the shield layer 150 includes a conductive layer, a dielectric layer, and a conductive layer similar to a MIM structure, the shield layer may operate as a capacitor. The shield layer 150 may serve as a capacitor (or a condenser) to constitute an LC resonant circuit together with the inductor 130 to be described later.

The shield layer 150 may include a first conductive layer 151, a dielectric layer 153, and a second conductive layer 155, which are stacked on the upper surface and the side surfaces of the package body 11.

The first conductive layer 151 may cover or at least partially cover the upper surface and the side surfaces of the package body 11. The first conductive layer 151 may be in contact with the first interconnection structure 101 of the package substrate 100, on side surfaces of the package substrate 100.

The dielectric layer 153 may be disposed on the first conductive layer 151. The dielectric layer 153 may include a dielectric material that electrically insulates layers disposed on opposite sides of the dielectric layer 153. The dielectric layer 153 may include, for example, a dielectric material having a dielectric constant of 20 [V/m] or more, for example, 20 to 30, or 20 to 25, but example embodiments are not limited thereto. The dielectric layer 153 may include at least one of zirconium oxide (ZrO₂) and hafnium oxide (HfO₂), but example embodiments are not limited thereto.

The second conductive layer 155 may be disposed on the dielectric layer 153. Electric conductivity of the second conductive layer 155 may be the same or substantially the same as electric conductivity of the first conductive layer 151, and a material of the second conductive layer 155 may be the same as a material of the first conductive layer 151. However, the electric conductivity of the second conductive layer 155 and the material of the second conductive layer 155 are not limited thereto, and may be different from the electric conductivity of the first conductive layer 151 and the material of the first conductive layer 151.

A conductive structure 160 may be disposed in contact with an outer side surface of the second conductive layer 155. The conductive structure 160 may provide an electrical connection path to the second conductive layer 155. In some example embodiments, a first voltage V1 and a second voltage V2 may be applied to the first conductive layer 151 and the second conductive layer 155, respectively. This will be described later.

The first conductive layer 151 and the second conductive layer 155 may include a conductive material. The first conductive layer 151 may include a metal such as tin (Sn), iron (Fe), nickel (Ni), or alloys thereof, but example embodiments are not limited thereto. The second conductive layer 155 may include a material, similar to a material of the first conductive layer 151. However, the materials of the first conductive layer 151 and the second conductive layer 155 are not limited to the above materials. For example, the first conductive layer 151 and the second conductive layer 155 may include steel used stainless (SUS).

Any or each of the plurality of layers, constituting the shield layer 150, may have a uniform thickness along the periphery of the package body 11, but example embodiments are not limited thereto. For example, a thickness of the plurality of layers stacked on the side surface of the package body 11 may be smaller than a thickness of the plurality of layers stacked on the upper surface of the package body 11. The dielectric layer 153 disposed on the upper surface of the package body 11 may have a larger thickness than at least one of the first and second conductive layers 151 and 155 disposed on the upper surface of the package body 11. The dielectric layer 153 may have a thickness of 5 μm or less, for example, 10 nm to 5 μm, or 50 nm to 2 μm, or 100 nm to 1 μm, but example embodiments are not limited thereto. Each of the first and second conductive layers 151 and 155 may have a thickness of 1 μm or less, for example, 100 nm to 1 μm, or 200 nm to 0.5 μm, but example embodiments are not limited thereto.

The inductor 130 may be provided on the upper surface of the package substrate 100 to be spaced apart from the semiconductor chip 110. The inductor 130, a type of passive electronic component, may include a conductor such as, for example, a coil, but example embodiments are not limited thereto. The inductor 130 may be provided in singular on a single package substrate 100. However, example embodiments are not limited thereto, and the inductor 130 may be provided in plural.

The inductor 130 may constitute (for example, form or be included in) an LC resonant circuit together with the above-described shield layer 150. The LC resonant circuit may be provided to eliminate or reduce interference between a signal interconnection and a power line within the semiconductor package and improve electrical characteristics.

The inductor 130 may include a body 131 and first and second terminals 133 and 135 provided on the body 131. The body 131 of the inductor 130 may include a spiral-shaped or meander-type interconnection, but example embodiments are not limited thereto. Any or each of the first and second terminals 133 and 135 of the inductor 130 may be connected to a capacitor, including the shield layer 150, to constitute a parallel LC resonant circuit. For example, the first terminal 133 and the second terminal 135 may be connected to a capacitor, including the shield layer 150, through interconnections of the package substrate and/or interconnections of a base substrate to be described later. For example, the first terminal 133 may be connected to the first conductive layer 151 through the first interconnection structure 101 and/or the second interconnection structure 10c, and the second terminal 135 may be connected to the second conductive layer 155 through the first interconnection structure 101, the second interconnection structure 10c, and/or the conductive structure 160. In more detail, the first terminal 133 of the inductor 130 may be connected to the first conductive layer 151 through interconnection patterns 101p and vias 101v of the first interconnection structure 101. At least a portion of the interconnection patterns 101p and the vias 101v may be in direct contact with the first conductive layer 151. The second terminal 135 of the inductor 130 may be electrically connected to the second conductive layer 155 through the interconnection patterns 101p and vias 101v of the first interconnection structure 101 of the package substrate 100, the second interconnection structure 10c of the base substrate 10, and the conductive structure 160.

The base substrate 10 may be disposed on one side of the package body 11 (below the package body 11, in the drawing). The base substrate 10 may be a substrate that fixes various electronic components to a surface thereof and connects the components by interconnections to form an electronic circuit, but example embodiments are not limited thereto.

The base substrate 10 may include interconnection to transmit signals and/or power. The interconnection of the base substrate 10 may include second upper pads 10a, second lower pads 10b, and a second interconnection structure 10c.

The base substrate 10 may be formed of an insulating material. For example, the base substrate 10 may include an insulating resin. The insulating resin may include a thermosetting resin such as an epoxy resin, a thermoplastic resin such as polyimide, or a resin impregnated with an inorganic filler in these resins, for example, prepreg, Ajinomoto Build-up Film (ABF), flame retardant (FR-4), and/or Bismaleimide Triazine (BT), but example embodiments are not limited thereto. For example, the base substrate 10 may include a photosensitive resin such as a photoimageable dielectric (PID). The base substrate 10 may include a plurality of insulating layers, not illustrated, stacked in a vertical direction. Depending on processes, boundaries between the plurality of insulating layers, not illustrated, may not be readily apparent.

The second upper pads 10a may be disposed above the base substrate 10. At least a portion of the second upper pads 10a may be provided in a corresponding location opposing a portion of the lower pads 100b of the first layer of the package substrate 100. For example, in cross-sectional view, at least a portion of the second upper pads 10a may be disposed on the same line as at least a portion of the first lower pads 100b of the package substrate 100. At least a portion of the second upper pads 10a may be disposed below the conductive structure 160 to provide an electrical connection path.

An upper surface of the second upper pad 10a may be exposed to the upper surface of the base substrate 10. The second upper pad 10a may include at least one of, for example, aluminum (Al), gold (Au), cobalt (Co), copper (Cu), nickel (Ni), lead (Pb), tantalum (Ta), tellurium (Te), titanium (Ti), tungsten (W), silver (Ag), molybdenum (Mo), zinc (Zn), platinum (Pt), or combinations thereof. The second lower pad 10b may be disposed below the base substrate 10 and may include a material, similar to a material of the second upper pad 10a. However, the materials of the second upper pad 10a and the second lower pad 10b are not limited to the above materials.

Although not illustrated, the second interconnection structure 10c may be formed in a multilayer structure including interconnection patterns and vias, similarly to the first interconnection structure 101. The second interconnection structure 10c may include signal interconnections, transmitting signals and power (hereinafter referred to as “signals”) to devices within the semiconductor package, such as the semiconductor chip 110, and capacitor interconnections for forming an LC resonant circuit. For ease of description, a signal transmission path of the second interconnection structure is simply denoted by dashed lines. In addition, it is noted that only a portion of the signal transmission path and a portion of the interconnection structure are illustrated in the drawings. For example, the signal transmission path may be provided in plural.

The second interconnection structure 10c may include for example, at least one of, for example, aluminum (Al), gold (Au), cobalt (Co), copper (Cu), nickel (Ni), lead (Pb), tantalum (Ta), tellurium (Te), titanium (Ti), tungsten (W), silver (Ag), molybdenum (Mo), zinc (Zn), platinum (Pt), or combinations thereof, but example embodiments are not limited thereto.

The second interconnection structure 10c may connect the second upper pads 10a and the second lower pads 10b to each other. In some example embodiments, a portion of the second interconnection structure 10c may be electrically connected to the signal interconnection 101a of the package substrate 100, and another portion thereof may be electrically connected to the capacitor interconnection 101b of the package substrate 100.

In some example embodiments, a plurality of connectors may be provided between the package body 11 and the base substrate 10 and below the base substrate 10. The plurality of connectors may include, for example, a first connector 171, provided between the package body 11 and the base substrate 10, and a second connector 173 provided below the base substrate 10.

The first connector 171 may electrically connect at least a portion of the first lower pads 100b of the package substrate 100 and the second upper pads 10a of the base substrate 10. The second connector 173 may electrically connect the second lower pads 10b of the base substrate 10 to other external devices. The first connector 171 may be provided to be in direct contact with the first lower pads 100b and the second upper pads 10a. The second connector 173 may be provided to be in contact (for example, direct contact) with the second lower pads 10b, and may electrically connect opposing components to each other. Various signals may be transmitted through the first and second connectors 171 and 173. The first connector 171 may include, for example, microbumps, metal pillars, ball grid array (BGA) solder balls, other various sized solder balls, cored solder balls, or combinations thereof. The second connector 173 may also include microbumps, metal pillars, ball grid array (BGA) solder balls, other various sized solder balls, cored solder balls, or combinations thereof, but example embodiments are not limited thereto. In some example embodiments, solder balls are provided as an example of the first and second connectors 171 and 173.

The first connector 171 and/or the second connector 173 may include, for example, tin (Sn), indium (In), bismuth (Bi), antimony (Sb), copper (Cu), silver (Ag), zinc (Zn), lead (Pb) and/or alloys thereof. Such alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like, but example embodiments are not limited thereto.

The first connector 171 and/or the second connector 173 may be provided in various types, various numbers, and various pitches depending on signals and power to be transmitted. For example, according to some example embodiments, the first connector 171 and/or the second connectors 173 may have a form in which metal pillars and solder balls are combined. At least a portion of the first connector 171 and/or the second connector 173 may be disposed in a location in which it does not overlap the semiconductor chip 110 in a vertical direction.

The conductive structure 160 may be disposed on the base substrate 10. The conductive structure 160 may be a conductive material such as iron (Fe), nickel (Ni), tin (Sn), or molybdenum (Mo), but example embodiments are not limited thereto. The conductive structure 160 may be disposed to be in contact with at least one layer of the shield layer 150, and may be in contact with the second conductive layer 155 of the shield layer 150. In some example embodiments, the second conductive layer 155 may be brought into contact with the conductive structure 160 to receive an electrical connection path.

An adhesive layer may be disposed between the conductive structure 160 and the base substrate 10. The adhesive layer may include an adhesive polymer material such as a polymer binder resin, an epoxy resin, a phenolic epoxy hardener, a curing catalyst, or a silane coupling agent, and may be in the form of a paste or a film, but example embodiments are not limited thereto. The adhesive layer may be disposed in a form that surrounds at least one of the second upper pads 10a disposed between the conductive structure 160 and the base substrate 10. The second upper pad 10a may, for example, have the same or substantially the same thickness as the adhesive layer.

The semiconductor package having the above-described structure may transmit a signal SG from the outside to the semiconductor chip 110 and/or from the semiconductor chip 110 to the outside.

The signal SG, transmitted from the outside to the semiconductor chip 110 or vice versa, may be implemented by electrically connecting interconnections, formed on each of the package substrate 100 and the base substrate 10, to the first and second connectors 171 and 173, a wire 111, or the like. For example, a signal from the outside to the semiconductor chip 110 may be transmitted to the second lower pad 10b of the base substrate 10 through (for example, by) the second connector 173 and sequentially through the second interconnection structure 10c, the second upper pad 10a, the first connector 171, the first interconnection structure 101, the signal interconnection 101a, the first upper pad 100a, and the wire 111, and a signal from the semiconductor chip 110 to the outside may be transmitted in an opposite direction.

The semiconductor package having the above-described structure may eliminate or reduce noise and interference, occurring in the semiconductor chip 110, signal interconnections, and power interconnections within the semiconductor package, by forming an LC resonant circuit using a capacitor, including the shield layer 150, and the inductor 130. For example, in a process of depositing a plurality of conductive layers, including a layer for shielding, on a side surface and an upper surface of the package body 11, a process of depositing a dielectric layer 153 may be additionally performed, and an electrical connection relationship may be added to a portion of the plurality of conductive layers. Accordingly, a semiconductor package using the dielectric layer 153 as a portion of a capacitor may be easily provided, and the inductor 130, a passive element, may be disposed inside the semiconductor package to easily eliminate or reduce noise and interference occurring in the semiconductor package.

The LC resonant circuit, including the capacitor and the inductor 130, may be, for example, a parallel resonant circuit in which the capacitor and the inductor 130 are connected in parallel. The parallel LC resonant circuit may operate as a bandstop resonator to block or impede signals in a specific band. In some example embodiments, the LC resonant circuit may be used as, for example, a resonant circuit eliminating or reducing noise and/or interference of power and signals supplied to the semiconductor chip 110.

A more detailed description will now be provided with reference to FIG. 2. A first voltage V1 and a second voltage V2 may be applied to opposite ends of the capacitor including the shield layer 150, for example, the first conductive layer 151 and the second conductive layer 155. For example, a first voltage V1 may be applied to the first conductive layer 151, and a second voltage V2 may be applied to the second conductive layer 155.

Applying the first voltage V1 to the first conductive layer 151 may be implemented through the interconnections formed on the package substrate 100 and the base substrate 10. For example, the first voltage V1 may be transmitted to the second lower pad 10b of the base substrate 10 through the second connector 173 and sequentially through the second interconnection structure 10c, the second upper pad 10a, the first connector 171, and the capacitor interconnection 101b of the first interconnection structure 101. The capacitor interconnection 101b may be, for example, provided in a form in which at least a portion of the capacitor interconnection 101b is in direct contact with the first conductive layer 151 to be electrically connected to the first conductive layer 151, but example embodiments are not limited thereto.

Applying the second voltage V2 to the second conductive layer 155 may be implemented through (for example, by) the interconnection, formed on the base substrate 10, and the conductive structure 160. For example, the second voltage V2 may be transmitted to the second lower pad 10b of the base substrate 10 through the second connector 173 and sequentially through the second interconnection structure 10c, the second upper pad 10a, and the conductive structure 160. The conductive structure 160 may be provided in a form in which at least a portion of the conductive structure 160 is in contact (for example, direct contact) with a side surface of the second conductive layer 155 to be electrically connected to the second conductive layer 155, but example embodiments are not limited thereto.

In some example embodiments, the first voltage V1 applied to the first conductive layer 151 may be larger than the second voltage V2 applied to the second conductive layer 155. The first voltage V1 may be, for example, a power supply voltage Vdd and the second voltage V2 may be, for example, a ground voltage Vss, but example embodiments are not limited thereto.

In some example embodiments, the inductor 130 may be connected in parallel to the capacitor. Opposite terminals of the inductor 130, for example, the first terminal 133 and the second terminal 135, may be connected to opposite terminals of the capacitor, for example, the first conductive layer 151 and the second conductive layer 155. For example, the first terminal 133 of the inductor 130 may be electrically connected to the first conductive layer 151 of the shield layer 150, and the second terminal 135 of the inductor 130 may be electrically connected to the second conductive layer 155 of the shield layer 150.

The connection of the inductor 130 and the capacitor of the shield layer 150 may be implemented by electrically connecting, for example, at least a portion of the first upper pad 100a, the first interconnection structure 101, the first lower pad 100b, first connector 171, the second upper pad 10a, the second interconnection structure 10c, and the conductive structure 160 of the package substrate 100. For example, the first terminal 133 of the inductor 130 may be connected to the first conductive layer 151, one end of the capacitor, through the first upper pad 100a of the package substrate 100 and the capacitor interconnection 101b of the first interconnection structure 101. The capacitor interconnection 101b may be provided in a form in which at least a portion of the capacitor interconnection 101b is in contact (for example, direct contact) with the first conductive layer 151, to be electrically connected to the first conductive layer 151. The second terminal 135 of the inductor 130 may be connected to an interconnection to which the second voltage V2 is applied. For example, the second terminal 135 of the inductor 130 may be electrically connected to the second voltage V2 on a path along which the second voltage V2 is applied to the second conductive layer 155. For example, the second terminal 135 may be applied with the second voltage V2 through the first upper pad 100a, the first interconnection structure 101, the first lower pad, the first connector 171, the second upper pad 10a, and the second interconnection structure 10c of the package substrate 100. The second voltage V2 may be equivalently or similarly applied to the conductive structure 160 and the second terminal 135 of the inductor 130, and a path for applying the second voltage V2 to the conductive structure 160 from the outside may be shared with a path for applying the second voltage V2 to the second terminal 135 of the inductor 130 from the outside.

The semiconductor package according to some example embodiments may be modified in various forms without departing from the scope of inventive concepts.

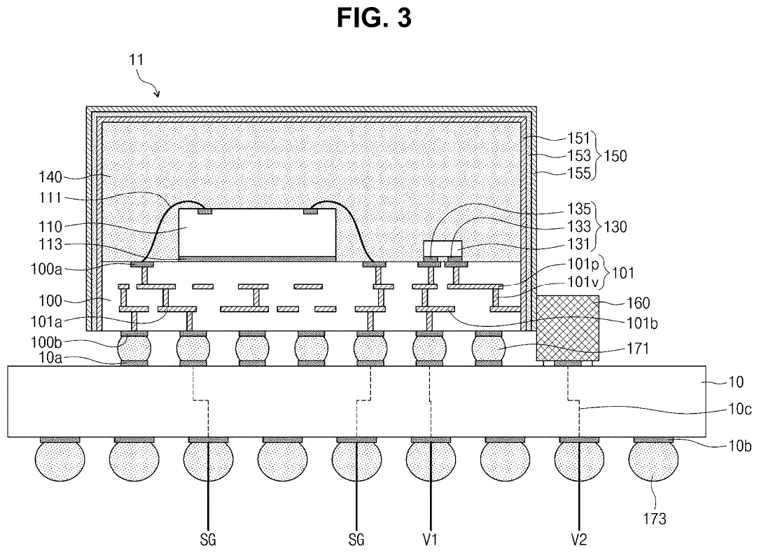

FIG. 3 is a cross-sectional view of a semiconductor package according to some example embodiments. In the following embodiments, differences from the above-described embodiments will be mainly described to avoid duplication of description.

Referring to FIG. 3, a semiconductor package according to some example embodiments may include a package body 11 including a semiconductor chip 110, a base substrate 10 on which the package body 11 is mounted, and a conductive structure 160 electrically connected to the package body 11. The package body 11 may include a semiconductor chip 110, a package substrate 100 on which the semiconductor chip 110 is mounted, an encapsulant 140 encapsulating the semiconductor chip 110, a shield layer 150 provided on the encapsulant 140, and an inductor 130 electrically connected to the shield layer 150. The inductor 130 may be connected in series to the capacitor of the shield layer 150 to form a series LC resonant circuit.

In some example embodiments, the inductor 130 may be provided on an upper surface of the package substrate 100 to be spaced apart from the semiconductor chip 110. The inductor 130 may include a body 131 and first and second terminals 133 and 135 provided on the body 131.

One of the first and second terminals 133 and 135 of the inductor 130 may be connected to one end of the capacitor to form a series LC resonant circuit. For example, the first terminal 133 may be connected to an external power supply, and the second terminal 135 may be connected to the first conductive layer 151 or the second conductive layer 155 of the capacitor, but example embodiments are not limited thereto.

For example, in some example embodiments, the first terminal 133 of the inductor 130 may be connected to an external power supply through interconnections of the package substrate 100 and the base substrate 10. For example, the first terminal 133 may be connected to an external power supply through a first upper pad 100a, a first interconnection structure 101, a first lower pad 100b, a first connector 171, a second upper pad 10a, a second interconnection structure 10c, and a second lower pad 10b. The second terminal 135 of the inductor 130 may be connected to the first conductive layer 151 through an interconnection patterns 101p and vias 101v of the first interconnection structure 101. At least a portion of the interconnection patterns 101p and vias 101v may be in contact (for example, direct contact) with the first conductive layer 151.

The semiconductor package having the above-described structure may transmit signals and/or power from the outside to the semiconductor chip 110 or from the semiconductor chip 110 to the outside.

Signals and power, transmitted from the outside to the semiconductor chip 110 or vice versa, may be implemented through interconnections formed on the package substrate 100 and the base substrate 10. For example, signals from the outside to the semiconductor chip 110 may be transmitted to the second lower pad 10b of the base substrate 10 through a second connector 173 and sequentially through a second interconnection structure 10c, a second upper pad 10a, a first connector 171, a signal interconnection 101a of the first interconnection structure 101, and the first upper pad 100a, and signals from the semiconductor chip 110 to the outside may be transmitted in an opposite direction, but example embodiments are not limited thereto.

In some example embodiments, a first voltage V1 and a second voltage V2 may be applied to a series LC resonant circuit including the inductor 130 and the shield layer 150. For example, the first voltage V1 may be applied to the first terminal 133 of the inductor 130, the second terminal 135 of the inductor 130 may be connected to the first conductive layer 151 of the shield layer 150, and the second voltage V2 may be applied to the second conductive layer 155 of the shield layer 150. The first voltage V1 applied to the first conductive layer 151 may be larger than the second voltage V2 applied to the second conductive layer 155. The first voltage V1 may be, for example, a power supply voltage Vdd and the second voltage V2 may be, for example, a ground voltage Vss, but example embodiments are not limited thereto.

For example, the first voltage V1 may be transmitted to the second lower pad 10b of the base substrate 10 through the second connector 173, and transmitted to the first upper pad 100a of the inductor 130 sequentially through the second interconnection structure 10c, the second upper pad 10a, the first connector 171, the first lower pad 100b, the capacitor interconnection 101b of the first interconnection structure 101, and the first upper pad 100a.

Electrical connection between inductor 130 and the first conductive layer 151 may be established by connecting the first terminal 133 of inductor 130 to the interconnections of the package substrate 100. For example, the first terminal 133 of the inductor 130 may be connected to the first conductive layer 151, one end of the capacitor, through the first upper pad 100a and the capacitor interconnection 101b of the first interconnection structure 101. The capacitor interconnection 101b may be provided in a form, in which at least a portion of the capacitor interconnection 101b is in contact (for example, direct contact) with the first conductive layer 151, to be electrically connected to the first conductive layer 151, but example embodiments are not limited thereto.

Applying the second voltage V2 to the second conductive layer 155 may be, for example, implemented through the interconnections, formed on the base substrate 10, and the conductive structure 160. For example, the second voltage V2 may be transmitted through the second connector 173 to the second lower pad 10b of the base substrate 10, and transmitted sequentially through the second interconnection structure 10c, the second upper pad 10a, and the conductive structure 160. The conductive structure 160 may be provided in a form, in which at least a portion of the conductive structure 160 is in direct contact with a side surface of the second conductive layer 155, to be electrically connected to the second conductive layer 155.

The semiconductor package having the above-described structure may selectively block signals. This is achieved using a series resonant circuit, in which the capacitor and inductor 130 are connected in series, acting as a bandpass resonator that allows only signals within a specific band to pass therethrough. The resonant circuit may be used as, for example, a resonant circuit eliminating or reducing noise and interference of power and signals supplied to the semiconductor chip 110.

In some example embodiments, an additional layer may be formed on the shield layer 150 constituting the capacitor.

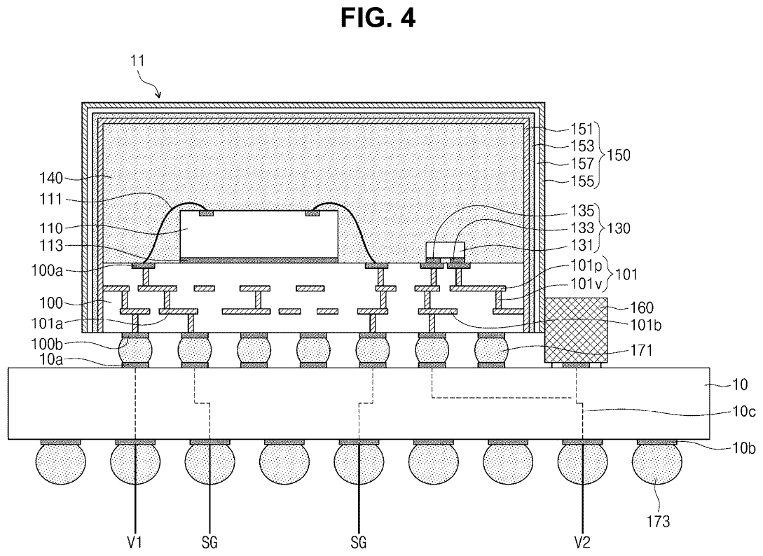

FIG. 4 is a cross-sectional view of a semiconductor package according to some example embodiments.

Referring to FIG. 4, the shield layer 150 may further include a third conductive layer 157 disposed between a dielectric layer 153 and a second conductive layer 155.

The third conductive layer 157 may be provided to shield the semiconductor package from electromagnetic interference (EMI) externally, but example embodiments are not limited thereto.

The conductivity of the first conductive layer 151 may be, for example, lower than the conductivity of the third conductive layer 157 disposed between the dielectric layer 153 and the second conductive layer 155. The conductivity of the third conductive layer 157 may be, for example, higher than the conductivity of the first conductive layer 151 and the second conductive layer 155. The third conductive layer 157 may include a conductive material. The third conductive layer 157 may include, for example, a metal including gold (Au), silver (Ag), copper (Cu), or any alloys thereof, but example embodiments are not limited thereto.

In some example embodiments, the second conductive layer 155 may be provided to reduce or prevent oxidation of the third conductive layer 157 disposed between the dielectric layer 153 and the second conductive layer 155, but example embodiments are not limited thereto. Accordingly, the conductivity of the second conductive layer 155 may be lower than the conductivity of the third conductive layer 157.

In some example embodiments, any or each of the first to third conductive layers 151, 155, and 157 may include a conductive material. The first conductive layer 151 may include, for example, a metal including tin (Sn), iron (Fe), nickel (Ni), or any alloys thereof, but example embodiments are not limited thereto. For example, the first conductive layer 151 may include steel used stainless (SUS). The third conductive layer 157 may include a material, similar or substantially similar to the material of the first conductive layer 151. However, the materials of the first to third conductive layers 151, 155, and 157 are not limited to the above materials. The second conductive layer 155 may include, for example, a metal including gold (Au), silver (Ag), copper (Cu), or alloys thereof, but example embodiments are not limited thereto.

According to some example embodiments, as described above, the EMI shielding ability of a semiconductor package may be improved by adding the third conductive layer 157 to the shield layer 150.

In some example embodiments, an LC resonant circuit of the semiconductor package may be applied to various semiconductor devices.

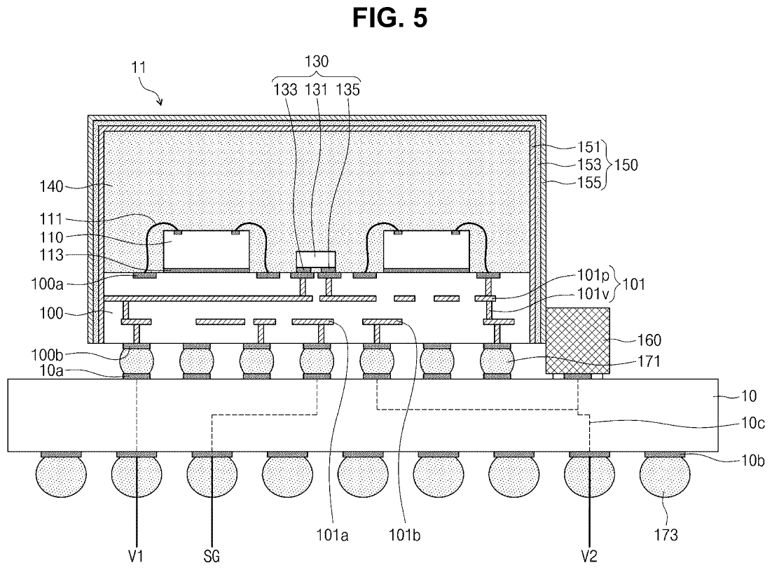

FIG. 5 is a cross-sectional view of a semiconductor package according to some example embodiments, illustrating that a semiconductor chip 110 is provided in plural.

Referring to FIG. 5, the semiconductor package may include a plurality of semiconductor chips 110.

The plurality of semiconductor chips 110 may be provided on an upper surface of a package substrate 100 to be spaced apart from each other. Each of the plurality of semiconductor chips 110 may be or include a semiconductor device including an integrated circuit. In some embodiments, the semiconductor package may have a package-on-package (POP) structure. An integrated circuit (IC) is generally a circuit formed on a semiconductor material such as silicon, and may be implemented by integrating a plurality of transistors, capacitors, inductors, resistors, or the like, into a die.

In FIG. 5, semiconductor chips 110 of the same type are illustrated as being formed on the package substrate 100 to be connected by wires. However, example embodiments are not limited thereto, and semiconductor chips 110 of different types may be provided. In addition, the number of the semiconductor chips 110 may be different from that illustrated in the drawing.

In addition, a portion or all of the plurality of semiconductor chips 110 may be provided in the form of a sub-package in which a plurality of semiconductor chips, rather than a single semiconductor chip 110, are stacked, but example embodiments are not limited thereto. For example, a semiconductor chip 110 provided in the form of a sub-package may have a structure in which a plurality of semiconductor chips 110 are stacked vertically and/or arranged horizontally. In addition, the semiconductor chip 110 provided in the form of a sub-package may include an inductor therein, and the inductor in the semiconductor chip 110 provided in the form of a sub-package may be used instead of an inductor 130 formed on the package substrate 100. Semiconductor chips provided in the form of a sub-package may include, for example, a system LSI, a flash memory, a DRAM, an SRAM, an EEPROM, a PRAM, an MRAM, or an RRAM, but example embodiments are not limited thereto.

In some example embodiments, an LC resonant circuit using a capacitor including the shield layer 150 and an inductor 130 may be formed according to a frequency band of noise generated by the semiconductor chips 110 in the semiconductor package. The LC resonant circuit may block or pass various frequency bands depending on a combination of inductance of the inductor 130 and capacitance of the capacitor of the shield layer 150. Accordingly, noise reduction of the semiconductor package may be increased or significantly increased by matching the inductance and capacitance to a noise generation element in the semiconductor package. For example, in a semiconductor package including two semiconductor chips 110, when noise generation of one of the semiconductor chips 110 is large or relatively large, the LC resonant circuit may be configured to block or reduce the noise or interference occurring in the one semiconductor chip 110. For example, a size and a location of the inductor 130 in the semiconductor package may be changed to significantly reduce noise and interference for various frequencies in the semiconductor package.

In some example embodiments, the semiconductor chip 110 may be provided in various types.

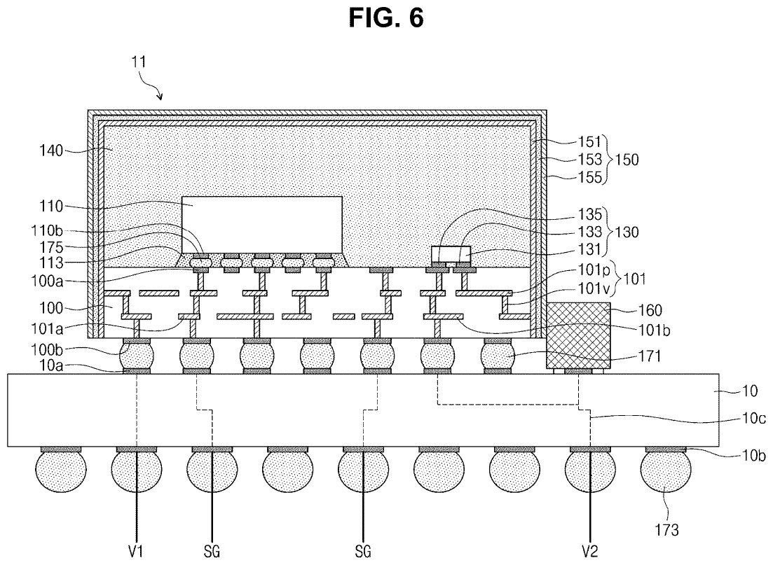

FIG. 6 is a cross-sectional view illustrating that the semiconductor chip 110 is provided as a flip chip in some example embodiments.

Referring to FIG. 6, the semiconductor chip 110 may be disposed above a package substrate 100 using an adhesive element 113 (or an ‘underfill layer’).

A third connector 175 may be provided between the semiconductor chip 110 and the package substrate 100 to electrically connect the semiconductor chip 110 and the package substrate 100. Various types of connectors, for example, microbumps, may be used as the third connector 175. A third lower pad 110b for connection to the third connector 175 may be provided below the semiconductor chip 110. The third lower pad 110b may be provided in a variety of numbers and pitches, and may be provided in the same number and pitch as a portion of the first upper pad 100a. However, the third connector 175 may be provided in a different form, for example, one of C4 bumps, microbumps, conductive pillars, solder balls for ball grid arrays, cored solder balls, or Cu—Cu bonding, but example embodiments are not limited thereto.

The adhesive element 113 may be, for example, an underfill layer surrounding connectors, disposed between the package substrate 100 and the semiconductor chip 110, among the connectors and fixing the semiconductor chip 110 to the package substrate 100. The underfill layer may include an insulating material. The underfill layer may be formed using, for example, a capillary underfill (CUF) process, but example embodiments are not limited thereto.

In some example embodiments, an inductor 130 may be provided in various forms. In the above-described embodiment, the inductor 130 is illustrated as being manufactured as an additional element and mounted on the package substrate 100. However, example embodiments are not limited thereto, and various types of inductor may be used. For example, a ferrite core inductor, an iron powder inductor, a bobbin-based inductor, a multilayer ceramic inductor, or a film inductor may be used as the inductor 130. In addition, the inductor 130 may be used in various ways depending on a method of connection with other electronic devices, such as insertion type, soldering type, or substrate-embedded type. According to some example embodiments, an inductor embedded in the package substrate 100 may also be used as the inductor 130.

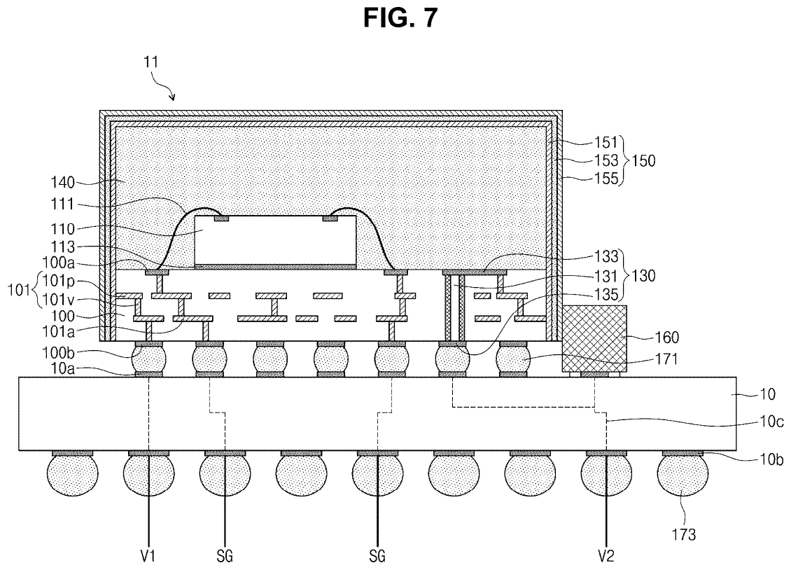

FIG. 7 is a schematic cross-sectional view of a semiconductor package according to some example embodiments, illustrating that the inductor 130 is embedded in the package substrate 100.

Referring to FIG. 7, the inductor 130 may include a first terminal 133 provided on an upper surface of a package substrate 100, a second terminal 135 provided on a lower surface of the package substrate 100, and a body 131 provided inside the package substrate 100. Although not illustrated in the drawing, the body 131 may include, for example, an insulating layer and an internal coil formed within a magnetic layer, but example embodiments are not limited thereto. The internal coil may, for example, include conductor patterns patterned in a strip shape on a plurality of insulating layers, and the conductor patterns may be connected to each other to form an overall internal coil, but example embodiments are not limited thereto.

The first terminal 133 provided on the upper surface of the package substrate 100 may be formed to be integrated (for example, integrally formed) with the first upper pad 100a, or the first terminal 133 and the first upper pad 100a may be formed separately and connected to each other. The second terminal 135 provided on the lower surface of the package substrate 100 may be formed to be integrated with the first lower pad 100b, or the second terminal 135 and the first lower pad 100b may be formed separately and connected to each other. In some example embodiments, the first terminal 133 and the second terminal 135 of the inductor 130 are illustrated as being formed on the upper and lower surfaces of the package substrate 100. However, example embodiments are not limited thereto, and the first terminal 133 and the second terminal 135 may be, for example, formed only on the upper surface of the package substrate 100, or only on the lower surface of the package substrate 100.

The first terminal 133 and the second terminal 135 of the inductor 130 may be connected to first and second conductive layers 151 and 155 through interconnections provided on a package substrate 100 and a base substrate 10, respectively. For example, the first and second terminals 133 and 135 of the inductor 130 may be connected to the first conductive layer 151 and the second conductive layer 155 through at least a portion of a first upper pad 100a, a first lower pad 100b, a first interconnection structure 101, a second upper pad 10a of a base substrate 10, a second lower pad 10b, a second interconnection structure 10c, and a conductive structure 160. For example, the first terminal 133 of the inductor 130 may be connected to the first conductive layer 151 through (for example, by) the first interconnection structure 101, but example embodiments are not limited thereto. The second terminal 135 of the inductor 130 may be connected to the second conductive layer 155 through the first lower pad 100b, the second upper pad 10a, the second interconnection structure 10c, and the conductive structure 160, but example embodiments are not limited thereto.

According to some example embodiments, the conductive structure electrically connecting the second conductive layer 155 and the base substrate 10 may be modified in various forms.

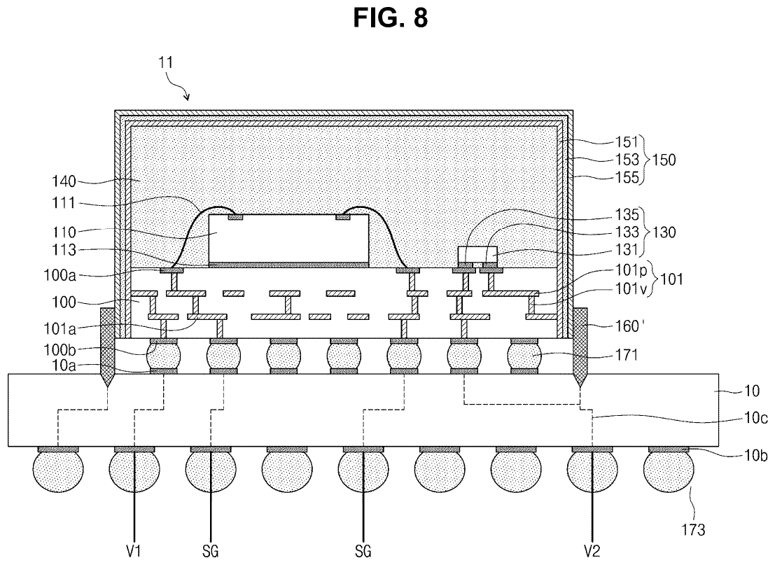

FIG. 8 is a cross-sectional view of a semiconductor package according to some example embodiments, illustrating that a conductive structure is formed to be different from a conductive structure according to the above-described embodiment.

Referring to FIG. 8, a semiconductor package according to some example embodiments may have a form in which a portion of a conductive structure 160′, disposed above a base substrate 10 and contacting an outer side surface of a shield layer 150, is inserted into a concave portion of the base substrate 10. For example, a portion of the conductive structure 160′ may be inserted into an insertion portion (for example, a socket) disposed on the base substrate 10 and may be electrically connected to a portion of a plurality of connection interconnections 117 of the base substrate 10.

In some example embodiments, the inductor 130 may be provided internally of the package body 11. However, example embodiments are not limited thereto, and the inductor 130 may be provided externally of the package body 11.

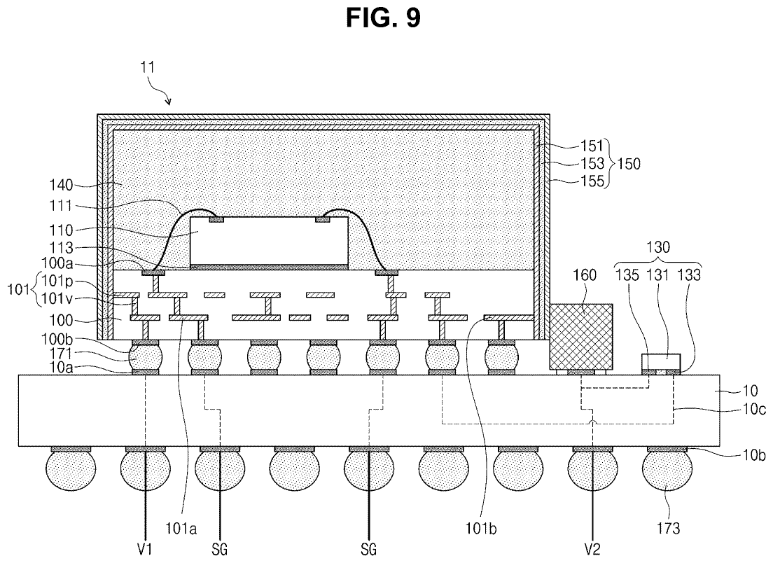

FIG. 9 is a cross-sectional view of a semiconductor package according to some example embodiments, illustrating that a location of the inductor 130 is different from the locations in the above-described embodiments.

Referring to FIG. 9, the inductor 130 may be provided on a base substrate 10 rather than a package substrate 100. The inductor 130 may be provided in a location spaced apart from a package body 11, for example, an encapsulant 140 and a shield layer 150. A first terminal 133 and a second terminal 135 of the inductor 130 may each be connected to a second upper pad 10a of the package body 11.

A first conductive layer 151 and a second conductive layer 155 of the shield layer 150 may be connected to the first and second terminals 133 and 135 of the inductor 130 provided to the outside through interconnections provided on the package substrate 100 and the base substrate 10. For example, the first terminal 133 of the inductor 130 may be connected to the first conductive layer 151 through the second upper pad 10a, a second interconnection structure 10c, a second upper pad 10a, a first connector 171, a first lower pad 100b, and a first interconnection structure 101. Interconnection patterns 101p and vias 101v of the first interconnection structure 101 may be in contact (for example, direct contact) with the first conductive layer 151. The second terminal 135 of the inductor 130 may be electrically connected to the second conductive layer 155 through the second upper pad 10a of the base substrate 10, the second interconnection structure 10c, the second upper pad 10a, and a conductive structure 160.

Unlike some above-described example embodiments, in some example embodiments, the conductive structure 160 and the base substrate 10 of the semiconductor package may be omitted.

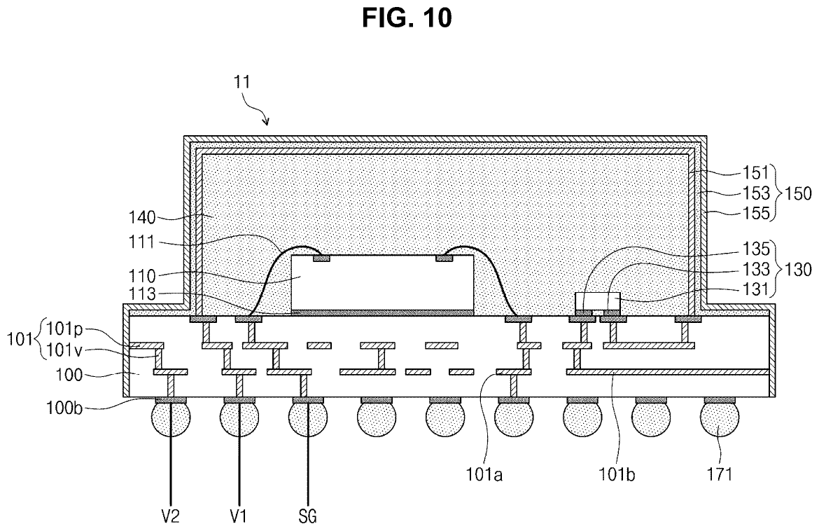

FIG. 10 is a cross-sectional view of a semiconductor package according to some example embodiments.

Referring to FIG. 10, a package substrate 100 may be provided to have a larger area than an encapsulant 140, and the encapsulant 140 may be provided on the package substrate 100. For example, a horizontal area of the encapsulant 140 covering a semiconductor chip 110 may be smaller than a horizontal area of the package substrate 100. A side surface of the semiconductor chip 110 may or may not be coplanar or substantially coplanar with a side surface of the encapsulant 140. For example, a side surface of the package substrate 100 may be disposed outside (for example, laterally away from) the side surface of the encapsulant 140, but example embodiments are not limited thereto.

A shield layer 150 covering the package body 11 and the package substrate 100 may cover upper and side surfaces of the encapsulant 140, but an area covered by a first conductive layer 151, a second conductive layer 155, and/or a dielectric layer may be different from that in some of the above-described example embodiments. In addition, or alternatively, at least one layer of the shield layer 150 covering or at least partially covering the package body 11 may form a step, but example embodiments are not limited thereto.

The first conductive layer 151 may cover or at least partially cover a side surface and/or an upper surface of the encapsulant 140, and may be connected to at least a portion of first upper pads 100a exposed to an upper surface of the package substrate 100 from at least a portion of the upper surface of the package substrate 100. In some example embodiments, the first conductive layer 151 may not cover the upper surface of the package substrate 100. The first conductive layer 151 may be applied with a first voltage V1 through a first upper pads 100a connected to the first conductive layer 151, first interconnection structure 101, first lower pads 100b, and first connector 171.

The dielectric layer 153 may extend along a surface of the first conductive layer 151 and the remaining portion of the upper surface of the package substrate 100. In some example embodiments, the dielectric layer may not cover the side surface of the package substrate 100, or may only cover a portion of the side surface of the package substrate 100. However, when the dielectric layer 153 covers a portion of the side surface of the encapsulant 140, the second conductive layer 155 may cover the side surface of the encapsulant 140 in a portion that is not covered by the encapsulant 140, but example embodiments are not limited thereto.

The second conductive layer 155 may be disposed on the dielectric layer 153. The second conductive layer 155 may cover the upper and side surfaces of the encapsulant 140 as well as the upper and side surfaces of the package substrate 100. The second conductive layer 155 may be connected to a capacitor interconnection 101b of the first interconnection structure 101 of the package substrate 100 on the side surface of the package substrate 100. The capacitor interconnection 101b may provide an electrical connection path to the second conductive layer 155, and the second conductive layer 155 may be applied with a second voltage V2 through the capacitor interconnection 101b. The first voltage V1 applied to the first conductive layer 151 may be, for example, higher than the second voltage V2 applied to the second conductive layer 155, but example embodiments are not limited thereto.

The first terminal 133 of the inductor 130 may be connected to the first upper pad 100a and the capacitor interconnection 101b of the first interconnection structure 101, and the capacitor interconnection 101b may be connected to the first upper pad 100a connected to the first conductive layer 151. Thus, the first terminal 133 and the first conductive layer 151 may be electrically connected to each other. The second terminal 135 of the inductor 130 may be connected to the first upper pad 100a and the capacitor interconnection 101b of the first interconnection structure 101, and the capacitor interconnection 101b may be in contact (for example direct contact) with the second conductive layer 155 to provide an electrical connection path.

Unlike some of the above-described example embodiments, in some example embodiments, the conductive structure 160 and the base substrate 10 of the semiconductor package may be omitted, and the shield layer 150 may be formed to have a different shape.

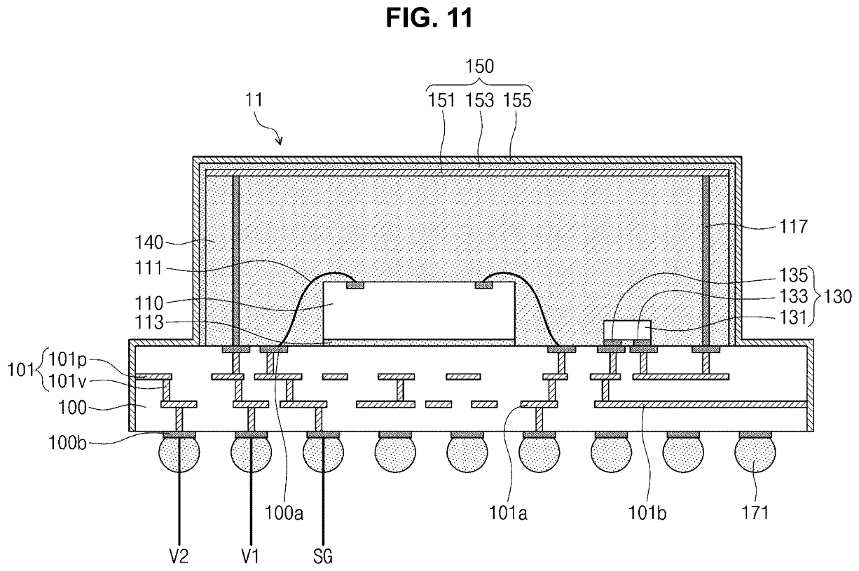

FIG. 11 is a cross-sectional view of a semiconductor package according to some example embodiments.

Referring to FIG. 11, a package substrate 100 may be provided to have a larger area than an encapsulant 140, and the encapsulant 140 may be provided on the package substrate 100. For example, a horizontal area of the encapsulant 140 covering the semiconductor chip 110 may be smaller than a horizontal area of the package substrate 100. A side surface of the semiconductor chip 110 may or may not be coplanar with a side surface of the encapsulant 140. For example, the side surface of the package substrate 100 may be disposed outside (for example, laterally apart from when moving in a direction away from the semiconductor chip 110) the side surface of the encapsulant 140.

The shield layer 150 covering or at least partially covering the package body 11 and the package substrate 100 covers the top and sides of the encapsulant 140, but an area covered by the first conductive layer 151, the second conductive layer 155, and the dielectric layer may be different from that in some of the above-described example embodiments. In addition, or alternatively, at least one layer of the shield layer 150 covering the package body 11 may form a step. The first conductive layer 151 may cover an upper surface of the encapsulant 140, but may not cover a side surface of the encapsulant 140 and upper and side surfaces of the package substrate 100, but example embodiments are not limited thereto.

A connection line 117 may be disposed within the encapsulant 140 to electrically connect the first conductive layer 151 and the second upper pad 10a. The connection line 117 may include a conductive material. The connection line 117 may include a metal, for example, solder (Sn), iron (Fe), nickel (Ni), or alloys thereof, but example embodiments are not limited thereto. The connection line 117 may, for example, be or have a pillar-shaped structure, but example embodiments are not limited thereto. For example, the connection line 117 may be in the form of a wire. In some example embodiments, a wire ball may be disposed below the connection line 117 to connect the wire body and the second upper pad 10a. The connection line 117 may be disposed to extend inside the encapsulant in a direction, for example, perpendicular or substantially perpendicular to the upper surface of the package substrate 100, but example embodiments are not limited thereto. For example, when the connection line 117 is in the form of a wire, the connection line 117 may extend in a direction, in which an arbitrary, predetermined, or desired angle (for example, greater than 0 degrees and less than 90 degrees) is formed with the upper surface of the package substrate 100, to be connected to the first conductive layer 151, but example embodiments are not limited thereto. The second interconnection structure 10c may, for example, provide an electrical connection path to the first conductive layer 151 through the second upper pad 10a and the connection line 117, and the first conductive layer 151 may be applied with a first voltage V1 through a second interconnection structure 10c.

The dielectric layer 153 may be disposed to cover an upper surface and a side surface of the first conductive layer 151 and/or a side surface of the encapsulant 140. The dielectric layer 153 may not cover the upper surface and the side surface of the package substrate 100. However, the shape of the dielectric layer 153 is not limited thereto, and the dielectric layer 153 may also cover at least a portion of the upper surface of the package substrate 100 and a portion of the side surface of the encapsulant 140. When, for example, the dielectric layer 153 covers a portion of the side surface of the encapsulant 140, the second conductive layer 155 may cover the side surface of the encapsulant 140 in a portion that is not covered by the encapsulant 140, but example embodiments are not limited thereto.

The second conductive layer 155 is disposed on the dielectric layer 153 and may extend along the side surface of the package substrate 100. The second conductive layer 155 may be connected to the capacitor interconnection 101b of the package substrate 100 on the side surface of the package substrate 100. The capacitor wire 101b may provide an electrical connection path to the second conductive layer 155, and the second conductive layer 155 may be applied with a second voltage V2 through the capacitor interconnection 101b. The first voltage V1 applied to the first conductive layer 151 may be, for example, higher than the second voltage V2 applied to the second conductive layer 155, but example embodiments are not limited thereto.

The first terminal 133 of the inductor 130 may be connected to the first conductive layer 151 through (for example, by) the above-described connection line 117. For example, the first terminal 133 of the inductor 130 may be connected to the first upper pad 100a and the capacitor interconnection 101b of the first interconnection structure 101, and the capacitor interconnection 101b may be connected to the first upper pad 100a connected to the connection line 117. Accordingly, the first terminal 133 and the first conductive layer 151 may be electrically connected to each other. The second terminal 135 of the inductor 130 may be connected to the first upper pad 100a and the capacitor wire 101b of the first interconnection structure 101, and the capacitor wire 101b may be in contact (for example, direct contact) with the second conductive layer 155 to provide an electrical connection path.

In some example embodiments, the shield layer 150 and the package substrate 100 of the semiconductor package may be provided to be different from those in some of the above-described example embodiments.

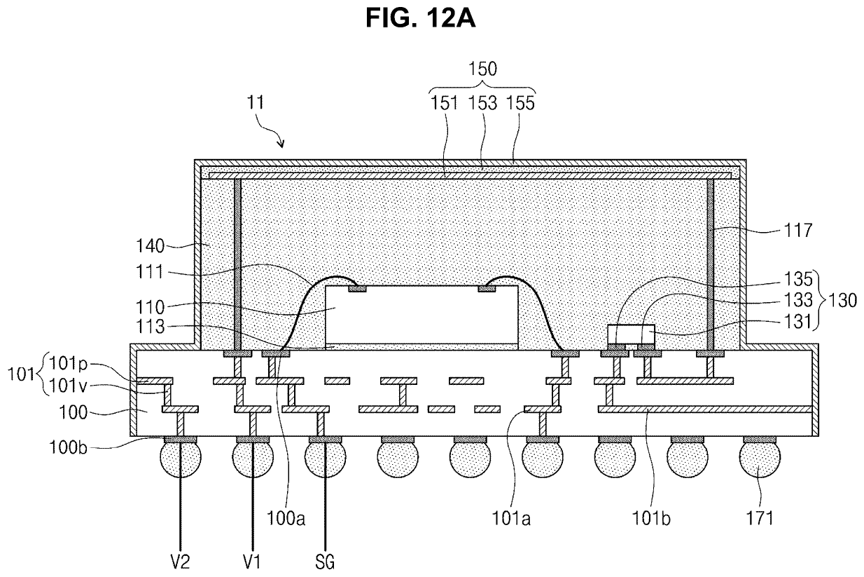

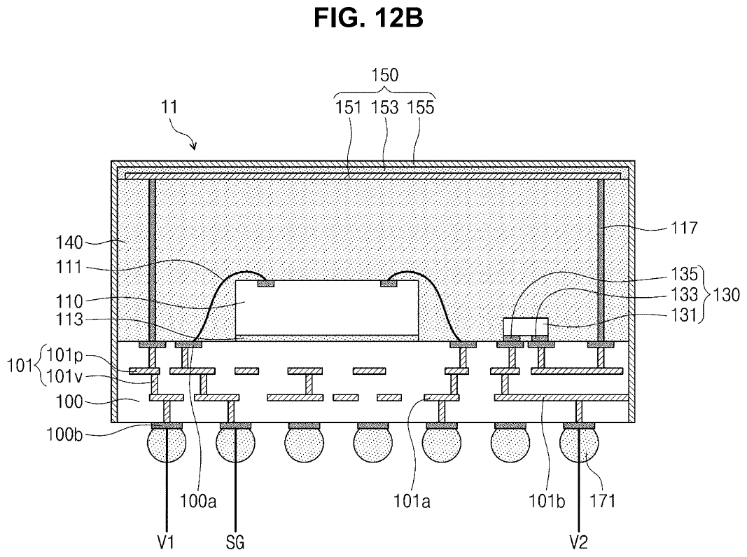

FIGS. 12A and 12B are each cross-sectional views of a package substrate 100 according to some example embodiments. In FIGS. 12A and 12B, except for a difference in area of a semiconductor package 100, the remaining components are provided in substantially the same forms.

Referring to FIG. 12A, the package substrate 100 may be provided to have the same or substantially the same area as an encapsulant 140. For example, a horizontal area of the encapsulant 140 covering a semiconductor chip 110 may be the same as a horizontal area of the package substrate 100, and a side surface of the semiconductor chip 110 may be coplanar with a side surface of the encapsulant 140.

Referring to FIG. 12B, a package substrate 100 may be provided to have a larger area than an encapsulant 140, and the encapsulant 140 may be provided on the package substrate 100. For example, a horizontal area of the encapsulant 140 covering a semiconductor chip 110 may be smaller than a horizontal area of the package substrate 100. A side surface of the semiconductor chip 110 may not be coplanar with a side surface of the encapsulant 140. For example, a side surface of the package substrate 100 may be disposed outside (for example, laterally apart in a direction moving away from the semiconductor chip 110) a side surface of the encapsulant 140.

Referring to FIGS. 12A and 12B, the first conductive layer 151 may cover or at least partially cover the upper surface of the encapsulant 140, and may not cover the side and upper surfaces of the package substrate 100. A connection line 117 may be disposed within the encapsulant 140 to electrically connect the first conductive layer 151 and the second upper pad 10a. The connection line 117 may include a conductive material. The connection line 117 may include, for example, a metal including solder (Sn), iron (Fe), nickel (Ni), or any alloys thereof, but example embodiments are not limited thereto. The connection line 117 may be or have a pillar-shaped or similarly structure, but example embodiments are not limited thereto. The connection line 117 may be disposed to extend in a direction, perpendicular to the upper surface of the package substrate 100 inside the encapsulant 140, but example embodiments are not limited thereto. The second interconnection structure 10c may provide an electrical connection path to the first conductive layer 151 through the second upper pad 10a and the connection line 117, and the first conductive layer 151 may be applied with a first voltage V1 through the second interconnection structure 10c.

The dielectric layer 153 may also cover or at least partially cover the upper surface of the encapsulant 140, and may not cover the side and upper surfaces of the package substrate 100. However, the shape of the dielectric layer 153 is not limited thereto, and the dielectric layer 153 may also cover at least a portion of the side surface of the encapsulant 140.

The second conductive layer 155 may be disposed on the dielectric layer 153 and may extend (for example, at least partially extend) along the side surface of the encapsulant 140 and the side surface of the package substrate 100. The second conductive layer 155 may be in contact (for example, direct contact) with at least a portion of the side surface of the encapsulant 140. The second conductive layer 155 may be connected to the capacitor interconnection 101b of the package substrate 100 on the side surface of the package substrate 100. The capacitor interconnection 101b may provide an electrical connection path to the second conductive layer 155, and the second conductive layer 155 may be applied with a second voltage V2 through the capacitor interconnection 101b. The first voltage V1 applied to the first conductive layer 151 may be higher than the second voltage V2 applied to the second conductive layer 155, but example embodiments are not limited thereto.

The first terminal 133 of the inductor 130 may be connected to the first conductive layer 151 through the above-described connection line 117. For example, the first terminal 133 of the inductor 130 may be connected to the first upper pad 100a and the capacitor interconnection 101b of the first interconnection structure 101, and the capacitor wire 101b may be connected to the first upper pad 100a connected to the connection line 117. Thus, the first terminal 133 and the first conductive layer 151 may be electrically connected to each other. The second terminal 135 of the inductor 130 may be connected to the first upper pad 100a and the capacitor interconnection 101b of the first interconnection structure 101, and the capacitor wire 101b may be in contact (for example, direct contact) the second conductive layer 155 to provide an electrical connection path.

As set forth above, according to example embodiments, a high-quality semiconductor package with significantly reduced electromagnetic interference (EMI) and reduced unwanted signals or noise may be provided.

While example embodiments have been shown and described above, it will be apparent to those ordinarily skilled in the art that modifications and variations could be made without departing from the spirit and scope of the present inventive concepts as in the appended claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A semiconductor package comprising:
a package substrate;
a semiconductor chip on the package substrate;
an encapsulant covering the semiconductor chip and at least a portion of the package substrate;
a shield layer covering at least a portion of the encapsulant and of the package substrate; and
an inductor connected to the shield layer as to form an LC resonant circuit,
wherein the shield layer comprises
a first conductive layer covering at least a portion of the encapsulant and of the package substrate, the first conductive layer configured to have a first voltage applied thereto;
a dielectric layer on the first conductive layer; and
a second conductive layer on the dielectric layer and configured to have a second voltage applied thereto.

2. The semiconductor package of claim 1, wherein
the shield layer forms a capacitor, and the inductor is connected in parallel to the capacitor.

3. The semiconductor package of claim 2, wherein
the inductor has a first terminal and a second terminal, the first terminal electrically connected to the first conductive layer and the second terminal electrically connected to the second conductive layer.

4. The semiconductor package of claim 1, wherein the shield layer forms a capacitor, and the inductor is connected in series to the capacitor.

5. The semiconductor package of claim 1, wherein
the first conductive layer is configured to have a first voltage applied thereto, and the second conductive layer is configured have a second voltage applied thereto, the second voltage being different from the first voltage.

6. The semiconductor package of claim 5, wherein
the first voltage is a power supply voltage, and the second voltage is a ground voltage.

7. The semiconductor package of claim 1, wherein
the shield layer further comprises a third conductive layer between the dielectric layer and the second conductive layer.

8. The semiconductor package of claim 1, further comprising:
a conductive structure in contact with an outer side surface of the second conductive layer and electrically connected to the second conductive layer; and
a base substrate below the package substrate and the conductive structure.

9. The semiconductor package of claim 8, wherein the inductor has a first terminal electrically connected to the first conductive layer, and the inductor has a second terminal electrically connected to the second conductive layer by the conductive structure.

10. The semiconductor package of claim 1, wherein
the first conductive layer, the dielectric layer, and the second conductive layer cover at least a portion of
an upper surface of the encapsulant,
a side surface of the encapsulant, and
a side surface of the package substrate.

11. The semiconductor package of claim 10, wherein
the first conductive layer covers at least a portion of the encapsulant, the dielectric layer is in contact with
the side surface of the encapsulant, and
at least a portion of the upper surface of the package substrate, and
the second conductive layer covers the encapsulant, the upper surface of the package substrate, and the side surface of the package substrate.

12. The semiconductor package of claim 11, further comprising:
a connection line at least partially extending through the encapsulant and electrically connecting the first conductive layer and a first terminal of the inductor.

13. The semiconductor package of claim 1, wherein
the inductor is at least partially embedded in the package substrate.

14. The semiconductor package of claim 1, wherein
the semiconductor chip includes a plurality of semiconductor chips, and the inductor is between ones of the plurality of semiconductor chips.

15. The semiconductor package of claim 1, wherein
the semiconductor chip is configured as a flip chip.

16. The semiconductor package of claim 1, wherein
the inductor is apart from the encapsulant and the shield layer.

17. The semiconductor package of claim 1, wherein
the package substrate comprises upper pads, lower pads, and a first interconnection structure, the first interconnection structure electrically connecting a first upper pad of the upper pads with a first lower pad of the lower pads.

18. The semiconductor package of claim 17, wherein
a portion of the first interconnection structure is electrically connected to at least one of the first conductive layer and the second conductive layer.

19. A semiconductor package comprising:
a package body comprising a semiconductor chip; and
a base substrate, the package body being on the base substrate,
wherein the package body comprises:
a semiconductor chip on a package substrate;
an encapsulant at least partially encapsulating the semiconductor chip;
an inductor on the package substrate; and
a shield layer covering at least a portion of the encapsulant and of the package substrate, and
the shield layer is a capacitor and forms an LC resonant circuit with the inductor.

20. A semiconductor package comprising:
a semiconductor chip;
an encapsulant at least partially encapsulating the semiconductor chip;
a shield layer on the encapsulant to form a capacitor having a metal-insulator-metal (MIM) structure; and
an inductor connected in series or parallel to the shield layer to form an LC resonant circuit.
